(19) United States
(12) Patent Application Publication
(10) Pub. No.: US 2012/0086120 A1
(43) Pub. Date: Apr. 12, 2012

(54) STACKED SEMICONDUCTOR PACKAGE HAVING CONDUCTIVE VIAS AND METHOD FOR MAKING THE SAME

(75) Inventors: Jen-Chuan Chen, Bade City (TW); Hui-Shan Chang, Jhongli City (TW); You-Cheng Lai, Zhongli City (TW)

(73) Assignee: Advanced Semiconductor Engineering, Inc., Kaohsiung (TW)

(21) Appl. No.: 13/253,816

(22) Filed: Oct. 5, 2011

(30) Foreign Application Priority Data
Oct. 7, 2010 (TW) 099134142

(51) Int. Cl. H01L 23/48

(52) U.S. Cl. 257/737; 257/E23.021

(57) ABSTRACT

The present invention relates to a stacked semiconductor package and a method for making the same. The method includes the steps of: forming and curing a first protective layer to cover a plurality of first bumps of a first wafer; cutting the first wafer to form a plurality of first dice; forming a third protective layer to cover a plurality of second bumps of a second wafer; picking up the first dice through the first protective layer, and bonding the first dice to the second wafer; removing part of the first protective layer; cutting the second wafer to form a plurality of second dice; and bonding the first dice and the second dice to a substrate. Whereby, the first protective layer can protect the first bumps, and the first protective layer can increase the total thickness and the flatness.

### RELATED APPLICATION

This application claims the benefit of Taiwan Application Ser. No. 099134142, filed Oct. 7, 2010, the subject matter of which is incorporated herein by reference.

### BACKGROUND OF THE INVENTION

1. Field of the Invention

The present invention relates to semiconductor packaging, and more particularly, to handling of stacked semiconductor packages during manufacture.

2. Description of the Related Art

A 3-D semiconductor package may be formed by stacking two dice on a substrate, wherein the bottom die disposed below the top die has a plurality of through silicon via (TSV) structures that protrude from a surface of the bottom die, and another surface of the bottom die has a plurality of bump structures (“bumps”). The conventional method for making such a semiconductor package has the following problems.

First, during the manufacture process, when a bonding head picks up the bottom die, the TSVs or the bumps can be damaged. Moreover, the upper die and the bottom die are extremely thin; therefore, it is quite challenging to pick up the thin dice and conduct a flip chip stacking process without causing damage. Further, the bonding head performs a heat pressing process under high temperature, during which solder may be softened and adhere to the bonding head.

### SUMMARY OF THE INVENTION

One aspect of the disclosure relates to a semiconductor device. In one embodiment, the semiconductor device includes a die having a first surface and a second surface, the die including a plurality of conductive vias formed therein, wherein each of the surfaces has a set of conductive elements, the set of conductive elements of the first surface including protruding ends of the conductive vias and the set of conductive elements of the second surface including a plurality of bumps, each of the bumps electrically connected to one of the conductive vias; and a protective layer covering one of the sets of conductive elements. In this embodiment, the protective layer can be a non-conductive film, made of a B-stage material. The non-conductive film is hard at room temperature, becomes soft at B-stage temperature, and is cured at higher temperatures. The protective layer protects the delicate conductive elements (i.e., the bumps or the conductive via tips) when the die is picked up by a bonding head as well as increases the total thickness and the flatness of the structure making it easier to pick up without causing damage.

Another aspect of the disclosure relates to a semiconductor package that includes a substrate; a first die, bonded to the substrate, having a first surface and a second surface, the first die including a plurality of first conductive vias formed therein and protruding from the first surface, and a plurality of first bumps disposed adjacent to the second surface, each of the conductive vias electrically connected to one of the first bumps; a first protective layer disposed adjacent to the second surface, the first bumps protruding from the first protective layer; a second protective layer, disposed between an upper surface of the substrate and the first protective layer; and a second die, coupled to the first die. The second die includes a third surface and a fourth surface, a plurality of second bumps disposed adjacent to the third surface, the second bumps being electrically connected to the first conductive vias. The semiconductor package can include a third protective layer, disposed between the first surface of the first die and the third surface of the second die.

Another aspect of the disclosure relates to a semiconductor package that includes a substrate; a first die, bonded to the substrate, having a first surface and a second surface, the first die including a plurality of first conductive vias formed therein and protruding from the first surface, and a plurality of first bumps disposed adjacent to the second surface, each of the conductive vias electrically connected to one of the first bumps; a first protective layer disposed adjacent to the first surface, the first conductive vias protruding from the first protective layer; a second protective layer, disposed between an upper surface of the substrate and the second surface; and a second die, coupled to the first die. The second die includes a third surface and a fourth surface, a plurality of second bumps disposed adjacent to the third surface, the second bumps being electrically connected to the first conductive vias. The semiconductor package can include a third protective layer, disposed between the first surface of the first die and the third surface of the second die.

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

FIG. 1 is a cross-sectional view illustrating a stacked semiconductor package according to an embodiment of the present invention;

FIGS. 2 to 13 are cross-sectional views illustrating a method for making a stacked semiconductor package according to an embodiment of the present invention;

FIG. 14 is a cross-sectional view illustrating a stacked semiconductor package according to another embodiment of the present invention;

FIG. 15 is a cross-sectional view of a stacked semiconductor package according to another embodiment of the present invention;

FIG. 16 is a cross-sectional view illustrating a stacked semiconductor package according to another embodiment of the present invention;

FIG. 17 is a cross-sectional view illustrating a stacked semiconductor package according to another embodiment of the present invention;

FIG. 18 is a cross-sectional view illustrating a stacked semiconductor package according to another embodiment of the present invention; and

FIGS. 19 to 24 are cross-sectional views illustrating a method for making a stacked semiconductor package according to another embodiment of the present invention.

Common reference numerals are used throughout the drawings and the detailed description to indicate the same elements. The present invention will be more apparent from the following detailed description taken in conjunction with the accompanying drawings.

### DETAILED DESCRIPTION OF THE INVENTION

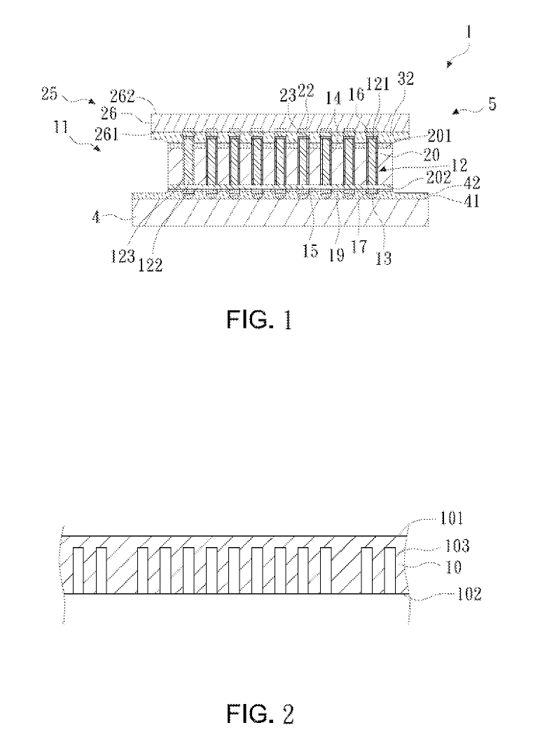

Referring to FIG. 1, a cross-sectional view of a semiconductor package 1 according to an embodiment of the present invention is illustrated. The stacked semiconductor package 1 comprises a package substrate 4, a first die 11, a first protective layer 19, a second protective layer 42, a second die 25, and a third protective layer 32.

The package substrate 4 has an upper surface 41. The first die 11 is bonded to the package substrate 4 at the upper surface 41. In this embodiment, the package substrate 4 provides an electrical connection between a stacked die structure 5 and other components (not shown). The first die 11 comprises a first die body 20, a plurality of first conductive vias 12, and a plurality of first bumps 13. In this embodiment, the first die body 20 is a functional die and is made of a semiconductor material, such as silicon, germanium, etc. However, in other embodiments, the first die body 20 can be an interposer. Each of the first conductive vias 12 comprise a conductive filler 122 and an insulation layer 123; the conductive filler 122 is made of conductive material, such as, copper, aluminum, silver, gold, etc. The insulation layer 123 is made of a dielectric inorganic material, such as silicon dioxide or a non-conductive polymer such as polyimide, epoxy or benzocyclobutene. The first die body 20 has a first surface 201 and a second surface 202. The first conductive vias 12 penetrate the first die body 20, and protruded ends 121 of the first conductive vias 12 protrude from the first surface 201. The first bumps 13 are disposed adjacent to the second surface 202 and electrically connected to the first conductive vias 12, and the first bumps 13 are electrically connected to the upper surface 41 of the package substrate 4. In this embodiment, the first bumps 13 are stacked structures of copper pillars and solder.

Preferably, the first die 11 is a processor die, and further comprises a passivation layer 14, a redistribution layer 15, a surface finish layer 16 and a plurality of first pads 17. The passivation layer 14 is disposed on the first surface 201, and the material of the passivation layer 14 is polymer material, such as, benzocyclobutene, polyimide, or epoxy; or, alternatively, a dielectric inorganic passivation layer, such as, for example, silicon dioxide. The redistribution layer 15 is disposed on the second surface 202. The first pads 17 are disposed on the redistribution layer 15, and the first bumps 13 are disposed on the first pads 17. The surface finish layer 16 is disposed on the protruded ends 121 of the first conductive vias 12.

The first protective layer 19 is disposed adjacent to the second surface 202, and the first bumps 13 protrude from the first protective layer 19. The second protective layer 42 is disposed between the upper surface 41 of the package substrate 4 and the first protective layer 19, so as to protect the first bumps 13. In this embodiment, the first protective layer 19 and the second protective layer 42 are non-conductive films. In another embodiment, the first protective layer 19 is a non-conductive film, such as benzocyclobutene, polyimide or epoxy, and the second protective layer 42 is an underfill.

The second die 25 is bonded to the first die 11 to form the stacked die structure 5. The second die 25 comprises a second die body 26 and a plurality of second bumps 23. The second die body 26 has a third surface 261 and a fourth surface 262, the second bumps 23 are disposed adjacent to the third surface 261, and the second bumps 23 are electrically connected to the first conductive vias 12.

In this embodiment, the second die 25 includes memory circuitry, and the second bumps 23 are made of solder. Moreover, the second die body 26 further comprises second pads 22 disposed adjacent to the third surface 261, and the second bumps 23 are disposed on the second pads 22.

The third protective layer 32 is disposed between the first surface 201 of the first die 11 and the third surface 261 of the second die 25, so as to protect the second bumps 23. In this embodiment, the third protective layer 32 is a non-conductive film or an underfill.

Referring to FIGS. 2 to 13, cross-sectional views of a method for making a stacked semiconductor package according to an embodiment of the present invention are illustrated. Referring to FIG. 2, a first semiconductor substrate 10 is provided. The first semiconductor substrate 10 has a first surface 101, a second surface 102, and a plurality of cylinders 103. In this embodiment, the first semiconductor substrate 10 is a silicon substrate, and the plurality of cylinders 103 are blind holes and open at the second surface 102. In this embodiment, the first semiconductor substrate 10 is functional and may further comprise active functions (not shown) on the second surface 102.

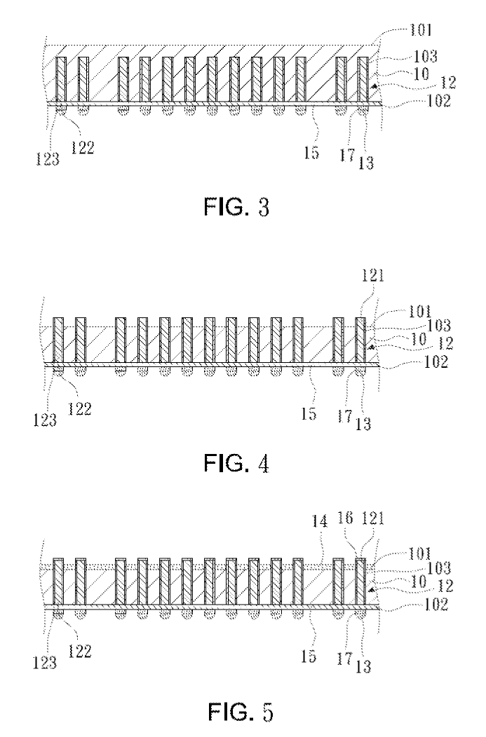

Referring to FIG. 3, the insulation layer 123 (e.g., an inorganic material, such as silicon dioxide or a non-conductive polymer such as polyimide, epoxy or benzocyclobutene) is disposed on the side wall of the plurality of cylinders 103, leaving a central portion of each of the plurality of cylinders 103 unfilled. Then, the unfilled portions of the plurality of cylinders are filled such as by plating the conductive fillers 122 with copper, aluminum, silver or gold, forming a plurality of first conductive vias 12. The redistribution layer 15 and a plurality of the first pads 17 are formed to electrically connect the conductive fillers 122. The redistribution layer 15 is disposed on the second surface 102 of the first semiconductor substrate 10. The first pads 17 are disposed on the redistribution layer 15, and the first bumps 13 are disposed on the first pads 17. In this embodiment, the first bumps 13 are stacked structures of copper pillars and solder. In another embodiment, the first bumps 13 may simply be copper pillars or solder. Then, the first semiconductor substrate 10 is turned downside up (“flipped”).

Referring to FIG. 4, the first semiconductor substrate 10 is thinned by removing part of the first surface 101 by means of grinding and/or etching, so that the cylinders 103 become a plurality of through holes 104, the conductive fillers 122 penetrate the first semiconductor substrate 10 with the protruded ends 121 of the first conductive vias 12 protruding from the first surface 101. In this embodiment, the first conductive vias 12 are electrically connected to the active functions (not shown) on the first surface 101.

Referring to FIG. 5, the passivation layer 14 is disposed on the first surface 101, and the material of the passivation layer 14 is a polymer material, such as benzocyclobutene, polyimide, or epoxy; alternatively, a dielectric inorganic passivation layer, such as, silicon dioxide, may be used. In this embodiment, the protruded ends 121 of the first conductive vias 12 protrude through the passivation layer 14 and the surface finish layer 16 is disposed on the protruded ends 121 of the first conductive vias 12.

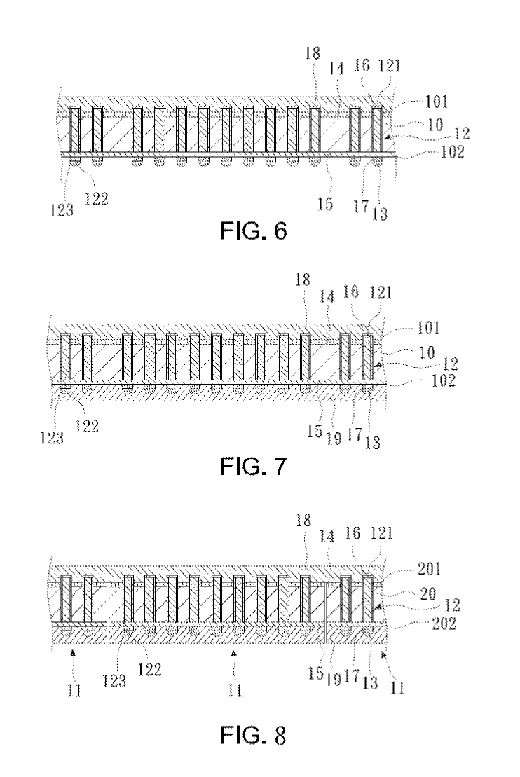

Referring to FIG. 6, a tape 18 is applied to cover and protect the protruded ends 121 of the first conductive vias 12. In this embodiment, the tape 18 is a dicing tape; however, in other embodiments, the tape 18 can be any other polymer tape.

Referring to FIG. 7, the first protective layer 19 is formed and cured on the first bumps 13, so as to cover and protect the first bumps 13. In this embodiment, the first protective layer 19 is a non-conductive film, which is a B-stage material, such as epoxy resin. The non-conductive film is hard at low temperatures, becomes soft at its B-stage temperature, and is cured at temperatures above its B-stage temperature. The first protective layer 19, while in sheet form, is attached to the second surface 102 of the first semiconductor substrate 10, and then, the first protective layer 19 is heated to the B-stage temperature, so that the first protective layer 19 is softened and flows so as to substantially completely cover the first bumps 13. Then the first protective layer 19 is additionally heated until it is cured. In addition to protecting the first bumps 13, the first protective layer 19 increases the total thickness and the flatness of the structure, which greatly facilitates the subsequent pick-up process. In this embodiment, the total thickness of the structure increases 3˜5 μm by using the first protective layer 19.

Referring to FIG. 8, the first semiconductor substrate 10 and the first protective layer 19 are cut, so as to form a plurality of first dice 11. Each of the first die 11 comprises the first die body 20, the first conductive vias 12 and the first bumps 13. The first die body 20 has a first surface 201 and a second surface 202. In this embodiment, the first die 11 is a functional die, e.g., the first die 11 includes processor circuitry. The first protective layer 19 and the first die 11 (formed after cutting) are still attached to the tape 18.

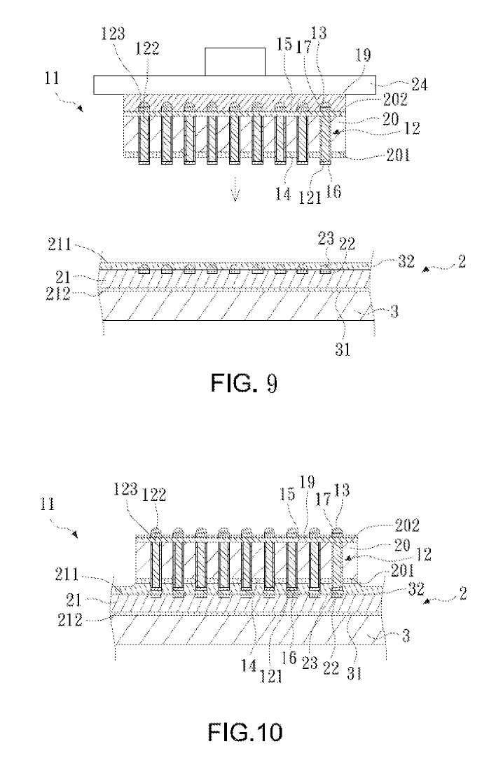

Referring to FIG. 9, in this embodiment a second wafer 2 and a carrier 3 are provided. The second wafer 2 comprises a second semiconductor substrate 21 and the plurality of the second bumps 23. The second semiconductor substrate 21 has a third surface 211 and a fourth surface 212. The second bumps 23 are disposed adjacent to the third surface 211, and the fourth surface 212 is attached to the carrier 3. In this embodiment, the second wafer 2 is a memory wafer, and preferably the second bumps 23 are solder bumps. Moreover, the second semiconductor substrate 21 further has a plurality of the second pads 22 disposed adjacent to the third surface 211, and the second bumps 23 are disposed on the second pads 22. The fourth surface 212 is attached to the carrier 3 by an adhesive layer 31. The third protective layer 32 is formed on the second bumps 23, so as to cover the second bumps 23. In this embodiment, preferably the third protective layer 32 is a non-conductive film or an underfill.

As illustrated, the first die 11 is picked up by a bonding head 24. Advantageously, the first bumps 13 are protected by the first protective layer 19 and will not contact the bonding head 24 directly. The first die 11 is then attached to the second die 2.

Referring to FIG. 10, the first conductive vias 12 contact and are electrically connected to the second bumps 23. Then, the bonding head 24 is removed, and part of the first protective layer 19 is removed so as to expose the first bumps 13. In this embodiment, part of the first protective layer 19 is removed such as by ashing or etching, so that the first protective layer 19 becomes thinner and exposes the first bumps 13.

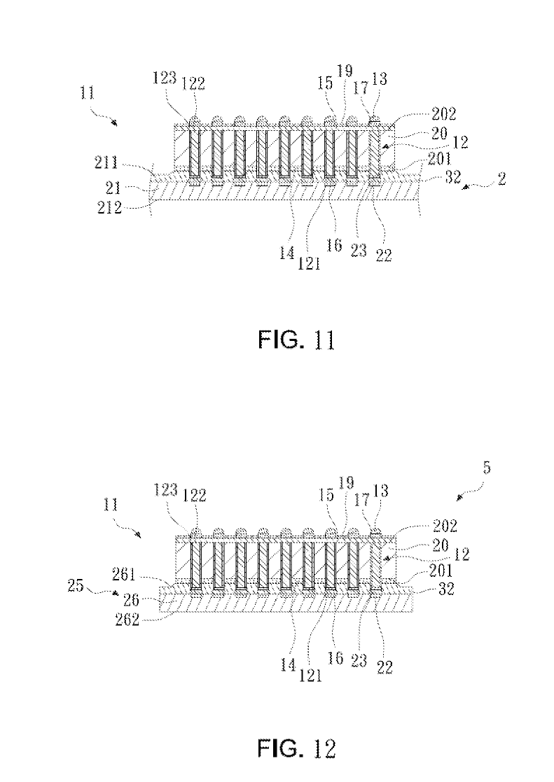

Referring to FIG. 11, the carrier 3 and the adhesive layer 31 are removed.

Referring to FIG. 12, the second wafer 2 is cut, so as to form a plurality of second dice 25. Each of the plurality of second die 25 comprises the second die body 26 and the second bumps 23. The second die body 26 has the third surface 261 and the fourth surface 262, and the second bumps 23 are disposed adjacent to the third surface 261. In this embodiment, the stacked structure of the first die 11 and one of the second dice 25 shows the stacked die structure 5.

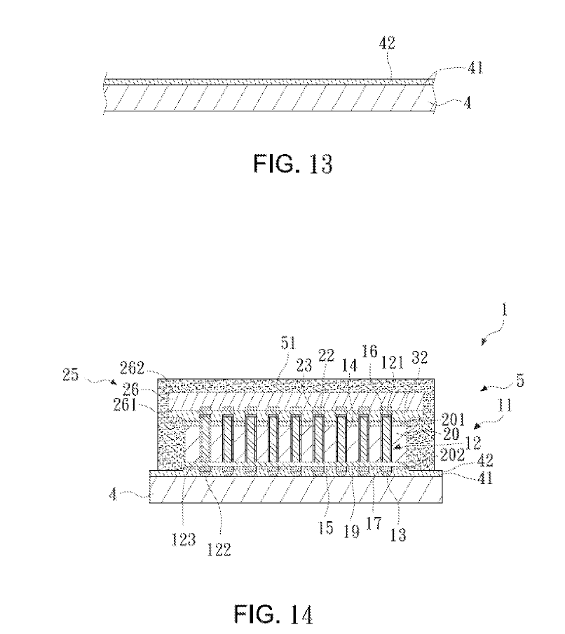

Referring to FIG. 13, the package substrate 4 provides an electrical connection between the stacked die structure 5 and other components (not shown). The package substrate 4 has the upper surface 41. The second protective layer 42 is formed on the upper surface 41 of the package substrate 4. In this embodiment, preferably the second protective layer 42 is a non-conductive film or an underfill.

The stacked die structure 5 of FIG. 12 is then bonded to the upper surface 41 of the package substrate 4, wherein the first bumps 13 are electrically connected to the upper surface 41 of the package substrate 4. Then, the package substrate 4 is cut so as to form the plurality of stacked semiconductor packages 1.

In another embodiment, the stacked die structure 5 may be bonded to the upper surface 41 of the package substrate 4 first, and then, the second protective layer 42 is further formed between the package substrate 4 and the first die 11.

Alternatively, as shown in FIG. 14, a molding compound 51 may be formed on the upper surface 41 of the package substrate 4 first, so as to encapsulate the first die 11 and the second die 25, and then, the package substrate 4 is further cut so as to form a plurality of stacked semiconductor packages.

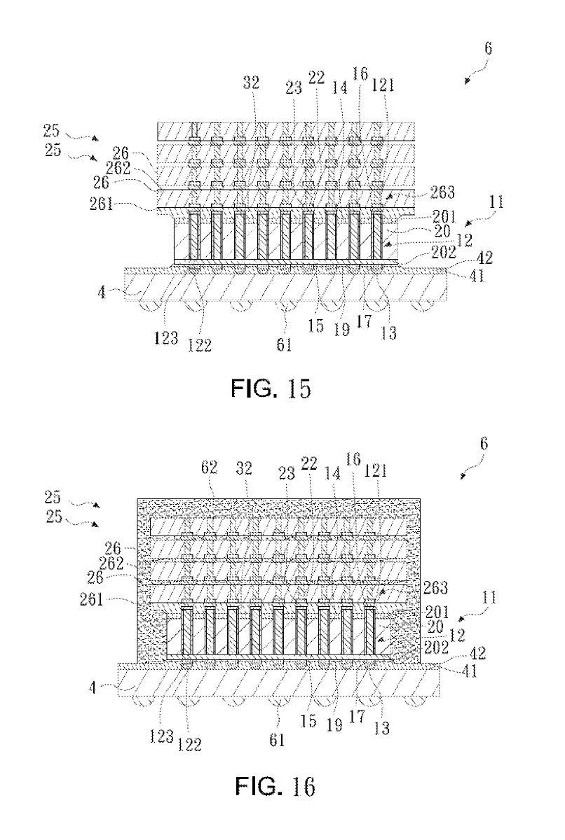

Referring to FIG. 15, a cross-sectional view of a stacked semiconductor package 6 according to another embodiment of the present invention is illustrated. The stacked semiconductor package 6 is similar to the stacked semiconductor package 1 of FIG. 1, and the same elements are designated by the same reference numbers. The difference between the stacked semiconductor package 6 and the stacked semiconductor package 1 is that additional dice are stacked together. These stacked second dice 25 are electrically connected to each other by the plurality of second conductive vias 263, the second bumps 23 and the second pads 22. Moreover, the stacked semiconductor package 6 further comprises a plurality of solder balls 61 disposed on a bottom surface of the package substrate 4.

Referring to FIG. 16, the stacked semiconductor package 6 further comprises a molding compound 62 disposed on the upper surface 41 of the package substrate 4, so as to encapsulate the first die 11 and the stacked second dice 25.

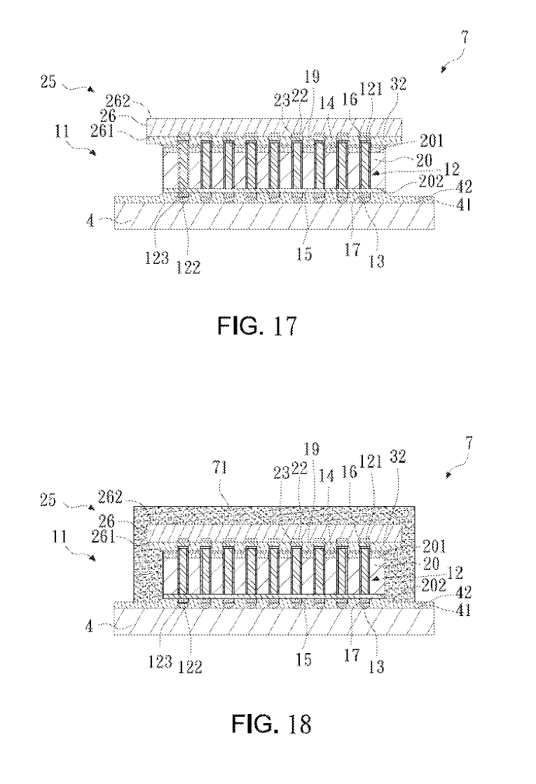

Referring to FIG. 17, a cross-sectional view of a stacked semiconductor package according to another embodiment of the present invention is illustrated. The stacked semiconductor package 7 is similar to the stacked semiconductor package 1 of FIG. 1, and the same elements are designated by the same reference numbers. The difference between the stacked semiconductor package 7 and the stacked semiconductor package 1 is the position of the first protective layer 19. In this embodiment, the bonding head 24 picks up the first die 11 through the first surface 201 and the first protective layer 19 is used to protect the first conductive vias 12. In this embodiment, the first protective layer 19 is disposed adjacent to the first surface 201 of the first die body 20, and the first conductive vias 12 protrude from the first protective layer 19. The third protective layer 32 is disposed between the first protective layer 19 and the third surface 261 of the second die 26, so as to protect the second bumps 23. The second protective layer 42 is disposed between the upper surface 41 of the package substrate 4 and the second surface 202 of the first die body 20, so as to protect the first bumps 13.

In the present invention, the first protective layer 19 can protect the first bumps 13 (semiconductor package 1 of FIG. 1) or the first conductive vias 12 (see semiconductor package 7 of FIG. 17), and the first protective layer 19 can increase the flatness, which facilitates the process of picking up the first die 11.

Referring to FIG. 18, the stacked semiconductor package 7 further comprises a molding compound 71 disposed on the upper surface 41 of the package substrate 4, so as to encapsulate the first die 11 and the second die 25.

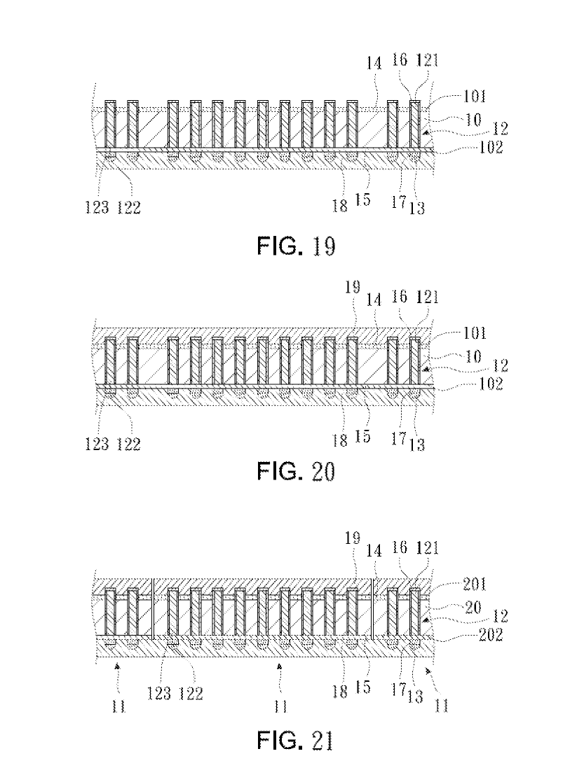

Referring to FIGS. 19 to 24, cross-sectional views of a method for making a stacked semiconductor package according to another embodiment of the present invention are illustrated. The method for making a stacked semiconductor package according to this embodiment is substantially the same as the method described above, and the same elements are designated by the same reference numbers. The formation of the first conductive vias 12 in this embodiment is the same as that of the embodiment of FIGS. 2-5, and is not described redundantly. Referring to FIG. 19, the tape 18 is applied to cover and protect the first bumps 13 after the protrusion of the first conductive vias 12 (FIG. 5).

Referring to FIG. 20, the first protective layer 19 is formed and cured on the protruded ends 121 of the first conductive vias 12, so as to cover the first conductive vias 12. In this embodiment, preferably the first protective layer 19 is a non-conductive film.

Referring to FIG. 21, the first semiconductor substrate 10 is cut, so as to form a plurality of first dice 11. Each of the first die 11 comprises the first die body 20, the first conductive vias 12 and the first bumps 13. The first die body 20 has a first surface 201 and a second surface 202. Meanwhile, the first protective layer 19 is cut together, and the first die 11 formed after cutting and the first protective layer 19 are still attached to the tape 18.

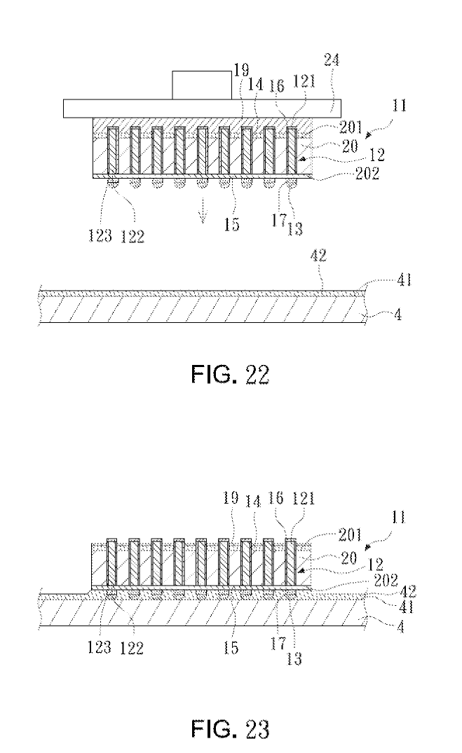

Referring to FIG. 22, a package substrate 4 having the upper surface 41 is provided. The second protective layer 42 is formed on the upper surface 41 of the package substrate 4. In this embodiment, the second protective layer 42 is a non-conductive film or an underfill. Then, the bonding head 24 picks up the first die 11 through the first protective layer 19, separates the first die 11 from the tape 18, and bonds the first die 11 to the package substrate 4, wherein the first bump 13 contacts and is electrically connected to the upper surface 41 of the package substrate 4.

In another embodiment, the first die 11 may be bonded to the upper surface 41 of the package substrate 4 first, and then, the second protective layer 42 is formed between the package substrate 4 and the first die 11.

Referring to FIG. 23, the bonding head 24 is removed, and part of the first protective layer 19 is removed, so that the first protective layer 19 becomes thinner and exposes the protruded end 121 of the first conductive vias 12.

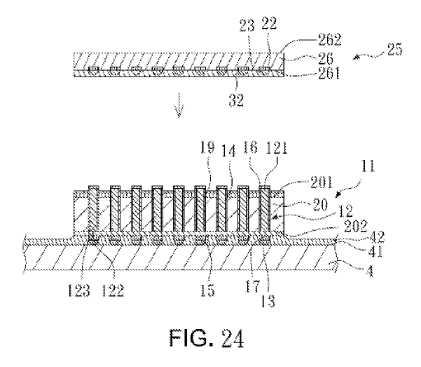

Referring to FIG. 24, the second die 25 and the third protective layer 32 are provided. The second die 25 comprises the second die body 26 and the plurality of the second bumps 23. The second die body 26 has the third surface 261 and the fourth surface 262. The second bumps 23 are disposed adjacent to the third surface 261. The third protective layer 32 is disposed on the second bumps 23, so as to cover the second bumps 23. In this embodiment, the second bumps 23 are solder bumps. Moreover, the second die body 26 further has the plurality of the second pads 22 disposed adjacent to the third surface 261, and the second bumps 23 are disposed on the second pads 22. The third protective layer 32 is disposed on the second bumps 23, so as to cover the second bumps 23. In this embodiment, the third protective layer 32 is a non-conductive film or an underfill.

In another embodiment, the third protective layer 32 may cover the first protective layer 19 of the first die 11 first.

The second die 25 is further bonded to the first die 11, wherein the second bumps 23 contact and are electrically connected to the first conductive vias 12. After cutting the package substrate 4, referring to FIG. 17 again, a plurality of stacked semiconductor packages 7 is formed.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not necessarily be drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor device, comprising:
a die having a first surface and a second surface, the die including a plurality of conductive vias formed therein, wherein each of the surfaces has a set of conductive elements, the set of conductive elements of the first surface including protruding ends of the conductive vias and the set of conductive elements of the second surface including a plurality of bumps, each of the bumps electrically connected to one of the conductive vias; and
a protective layer covering one of the sets of conductive elements.

2. The semiconductor device of claim 1, wherein an outer surface of the protective layer is substantially flat.

3. The semiconductor device of claim 1, wherein the protective layer is a non-conductive material.

4. The semiconductor device of claim 1, wherein the protective layer is a non-conductive film.

5. The semiconductor device of claim 1, wherein the protective layer is a B-stage adhesive.

6. The semiconductor device of claim 1, wherein the protective layer is heat cured.

7. A semiconductor package, comprising:
a substrate;
a first die, bonded to the substrate, having a first surface and a second surface, the first die including a plurality of first conductive vias formed therein and protruding from the first surface, and a plurality of first bumps disposed adjacent to the second surface, each of the conductive vias electrically connected to one of the first bumps;
a first protective layer disposed adjacent to the second surface, the first bumps protruding from the first protective layer;
a second protective layer, disposed between an upper surface of the substrate and the first protective layer; and
a second die, coupled to the first die.

8. The semiconductor package of claim 7, wherein the second die includes a third surface and a fourth surface, a plurality of second bumps disposed adjacent to the third surface, the second bumps being electrically connected to the first conductive vias.

9. The semiconductor package of claim 7, further comprising a third protective layer, disposed between the first surface of the first die and the third surface of the second die.

10. The semiconductor package of claim 7, wherein protruding ends of each of the first conductive vias include a surface finish layer.

11. The semiconductor package of claim 7, wherein the first die further includes a passivation layer and a redistribution layer, the passivation layer disposed on the first surface, and the redistribution layer disposed on the second surface.

12. The semiconductor package of claim 7, wherein the first bumps are solder, and the second bumps include copper pillars.

13. The semiconductor package of claim 7, wherein the first protective layer is a non-conductive film.

14. The semiconductor package of claim 7, wherein the second protective layer is a non-conductive film or an underfill.

15. The semiconductor package of claim 7, wherein the third protective layer is a non-conductive film or an underfill.

16. The semiconductor package of claim 7, further comprising a molding compound encapsulating the first die and the second die.

17. A semiconductor package, comprising:
a substrate;
a first die, bonded to the substrate, having a first surface and a second surface, the first die including a plurality of first conductive vias formed therein and protruding from the first surface, and a plurality of first bumps disposed adjacent to the second surface, each of the conductive vias electrically connected to one of the first bumps;
a first protective layer disposed adjacent to the first surface, the first conductive vias protruding from the first protective layer;
a second protective layer, disposed between an upper surface of the substrate and the second surface; and
a second die, coupled to the first die.

18. The semiconductor package of claim 17, wherein the second die includes a third surface and a fourth surface, a plurality of second bumps disposed adjacent to the third surface, the second bumps being electrically connected to the first conductive vias.

19. The semiconductor package of claim 18, further comprising a third protective layer, disposed between the first surface of the first die and the third surface of the second die.

20. The semiconductor package of claim 17, further comprising a molding compound encapsulating the first die and the second die.
